(19) United States
(12) Patent Application Publication
(10) Pub. No.: US 2003/0109092 A1
(43) Pub. Date: Jun. 12, 2003

(54) Surface smoothing device and method thereof

(76) Inventors: Won-Kook Choi, Seoul (KR); Hyung-Jin Jung, Seoul (KR); Jae-Hoon Song, Uijeongbu (KR); Hee-Bum Oh, Seoul (KR); Deok-Joo Yoon, Seoul (KR)

Correspondence Address: MCDERMOTT WILL & EMERY, 600 13TH STREET, N.W., WASHINGTON, DC, 20005-3096, US

(21) Appl. No.: 10/280,078

(22) Filed: Oct. 25, 2002

(30) Foreign Application Priority Data
Oct. 25, 2001 (KR) 66053/2001

(51) Int. Cl. H01L 21/8238

(52) U.S. Cl. 438/200

(57) ABSTRACT

A surface smoothing device and method thereof which flattens a surface of a sample by irradiating ionized gas of cluster state comprises: an operating gas supplying device for supplying operating gas; a diffusion chamber connected to a convergent and divergent nozzle which changes the operating gas supplied from the operating gas supplying device into cluster state; a source chamber including a skimmer connected to the diffusion chamber for extracting a part of the operating gas in cluster state, and an ionizing device for ionizing the operating gas of cluster state selected by the skimmer; an acceleration chamber including a lens for increasing a density of the cluster ion beam current, and an accelerating device for accelerating the cluster ion; and a process chamber in which the accelerated cluster ion is irradiated on a sample of ITO thin film to flatten the surface of the sample.

### BACKGROUND OF THE INVENTION

1. Field of the Invention

The present invention relates to a surface smoothing device and method thereof, and particularly, to a surface smoothing device and method thereof using a gas cluster ion beam which flattens a surface of a sample by irradiating gas in cluster state after ionizing and accelerating towards the surface of the sample.

2. Description of the Background Art

Generally, a surface of a material thin film used in ITO thin film or ULSI (Ultra Large Scale Integration) semiconductor processes should have higher flatness, and plasma or ion beam is used for flattening the surface.

The plasma or the ion beam used presently is a process using monoatom having lower sputtering yield, and therefore, high density plasma and high current density ion source are needed.

However, defectives may be generated on a surface of a sample by implantation (infiltration) into unwanted depth when the monoatomic materials are impacted on the surface in cleaning (washing) the surface and fabricating (functioning), and thereby, quality may be degraded when device is fabricated.

Meanwhile, if there is a hillock on the surface of the ITO thin film, a strong electric field is concentrated on the hillock. Therefore, the electric field should be removed in order to make uniformed color and to extend the life span in case that the ITO thin film is used as a transparent electrode of an organic electroluminescence (EL) devices.

In order to remove the hillock, high density plasma or ion beam were used conventionally. However, these have problems such as low sputtering yield and penetration (infiltration) of ion into unwanted region, and thereby a leakage path is formed to deteriorate the electronic characteristics.

In case of chemical mechanical polishing which is another method for removing the hillock, size and kinds of slurry which costs high should be changed according to processes.

In addition, a washing process for removing remaining slurry should be added to the processes, and therefore the processes become complex and price of the system rises.

### SUMMARY OF THE INVENTION

Therefore, an object of the present invention is to provide a surface smoothing device and method thereof using gas cluster ion beam for flattening a surface of a sample by changing operating gas into cluster state and by irradiating the gas in cluster state on the surface of sample after ionizing and accelerating the gas cluster ion.

To achieve the object of the present invention, as embodied and broadly described herein, there is provided a surface smoothing device using gas cluster ion beam comprising: an operating gas supplying device for supplying the operating gas; a diffusion chamber connected to convergent and divergent nozzle for changing the operating gas supplied from the operating gas supplying device into cluster state; a source chamber including a skimmer connected to the diffusion chamber for selecting and extracting a part of the operating gas in cluster state, and an ionizing device for ionizing the operating gas in cluster state selected and extracted by the skimmer; an accelerating chamber including a lens for increasing the cluster ion beam current density and an accelerating device for accelerating the cluster ion; and a process chamber for flattening a surface of a sample by irradiating the accelerated cluster ion on a sample.

Also, there is provided a surface smoothing method using gas cluster ion beam comprising: forming cluster by passing operating gas through a convergent and divergent nozzle and adiabatically expanding the gas into a diffusion chamber; selecting and extracting the formed cluster; ionizing the extracted cluster; accelerating the ionized cluster; and flattening a surface of a sample by irradiating the accelerated cluster on the surface.

The foregoing and other objects, features, aspects and advantages of the present invention will become more apparent from the following detailed description of the present invention when taken in conjunction with the accompanying drawings.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

In the drawings:

FIG. 1 is a sketch showing a surface smoothing device using gas cluster ion beam according to the present invention;

FIG. 2 is a cross-section of convergent and divergent nozzle in the surface smoothing device using the gas cluster ion beam according to the present invention;

FIG. 3 is a graph showing CO₂ cluster measured by time-of-flight (ToF) measuring method, when an operating gas passes through the convergent and divergent nozzle according to the present invention; and

FIGS. 4A, 4B, and 4C are respectively Atomic Force Microscope (AFM) images showing a surface of ITO thin film, a surface processed using CO₂ monomer ion beam, and a surface processed using CO₂ cluster ion according to the present invention.

### DETAILED DESCRIPTION OF THE PREFERRED EMBODIMENTS

Reference will now be made in detail to the preferred embodiments of the present invention, examples of which are illustrated in the accompanying drawings.

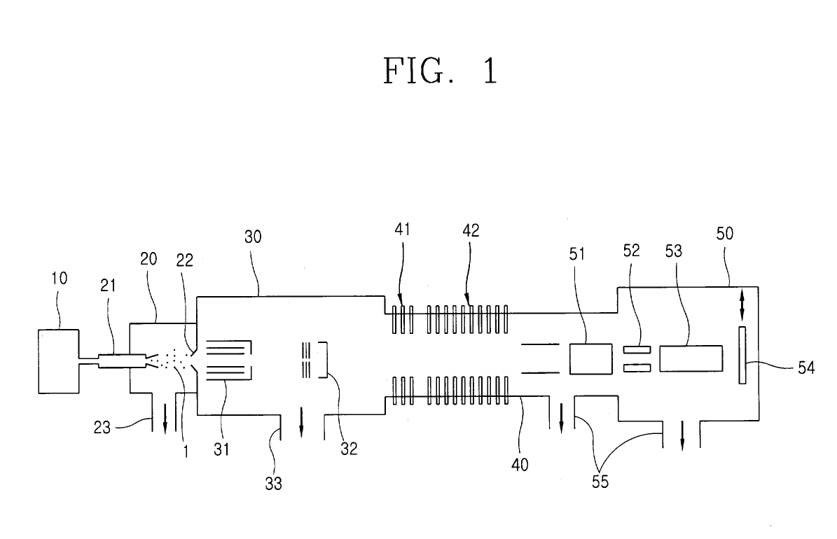

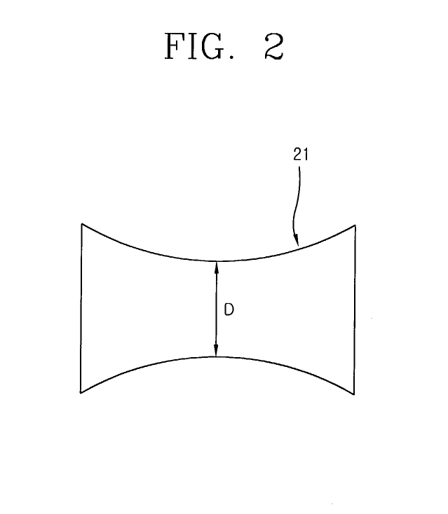

FIG. 1 is a sketch showing a surface smoothing device using gas cluster ion beam according to an embodiment of the present invention.

As shown therein, the surface smoothing device using the gas cluster ion beam according to the embodiment of the present invention comprises: an operating gas supplying device 10 for supplying operating gas 1; a diffusion chamber 20 connected to a convergent and divergent nozzle 21 changing the operating gas into cluster state and a skimmer 22 connected to the diffusion chamber 20 for selecting and extracting a part of the operating gas in cluster state; a source chamber 30 including an ionizing device 31 for ionizing the operating gas in cluster state selected and extracted by the skimmer 22; an acceleration chamber 40 including a lens for increasing a density of the cluster ion 1 and an acceleration device 42 for accelerating the operating gas in cluster state; and a process chamber 50 for flattening a surface of a sample 2 by irradiating the accelerated cluster ion 1 on the sample 2.

The operating gas 1 used for the surface smoothing device using the gas cluster ion beam may be one of the CO₂, SF₂, Ar, O₂, N₂O. Especially, in the embodiment of the present invention, the CO₂ gas in which the cluster is well formed at room temperature is used, the operating pressure in the operating gas supplying device 10 is maintained to be 5 atm regarding to that the cluster is generated when the pressure is 4 atm or more. That is, it is desirable that the pressure inside the operating gas supplying device 10 is maintained to be higher than that of generating cluster.

The convergent and divergent nozzle 21 is connected to the operating gas supplying device 10, and uses a quartz Laval nozzle having a diameter (D) on neck portion of 0.11 m. The operating gas 1 supplied from the operating gas supplying device 10 passes through the quartz Laval nozzle, that is, the convergent and divergent nozzle 21, and then adiabatically expands into the diffusion chamber 20 to be changed into the cluster state.

Meanwhile, the vacuum diffusion chamber 20 is connected to the convergent and divergent nozzle 21, and the pressure inside the diffusion chamber 20 is maintained to be about 70 mTorr by exhausting with a booster pump and a rotary pump 23 so as to generate pressure difference from that of the operating gas supplying device 10. That is, the operating gas 1 is adiabatically expanded by the pressure difference described above, and therefore, the cluster of the operating gas 1 is formed.

A core part of the cluster of the operating gas 1 formed as above is selected and extracted by the skimmer 22 installed between the vacuum diffusion chamber 20 and the source chamber 30. In the embodiment of the present invention, the diameter of the skimmer is 0.5 mm.

The ionizing device 31 is installed inside the source chamber 30 for ionizing the operating gas 1 in cluster state, selected and extracted by the skimmer 22.

In addition, a reflectron 32 may be installed inside the source chamber 30 for measuring the size of the cluster of the operating gas 1 passed through the ionizing device 31 by applying a retarding field. The pressure in the source chamber 30 is maintained to be 3×10⁻⁷ Torr by a turbo molecular pump 33.

The cluster of the operating gas 1 which was ionized by the ionizing device 31 is accelerated as passing through the acceleration chamber 40, and the acceleration is made by the acceleration device 42. In the present embodiment, the ionized cluster of the operating gas 1 can be accelerated till 150 kV by the acceleration device 42.

Meanwhile, the ionized cluster of the operating gas 1 may be focused by an einzel lens for increasing the ion current density installed between the ionizing device 31 and the acceleration device 42 before being accelerated.

The einzel lens is installed inside the acceleration chamber 40, and comprises three electrodes. Negative voltage is applied to a middle electrode, and both end electrodes are grounded, and thereby the cluster of the operating gas 1 is focused.

The cluster of the operating gas 1 which was accelerated as passing through the acceleration chamber 40 is irradiated on the surface of the sample 2 in the process chamber 50, and accordingly, the surface of the sample 2 is flattened.

Herein, a scanner 51 may be installed in the process chamber 50 in order to control the irradiation position of the cluster of the operating gas. The pressure in the process chamber 50 is controlled by the turbo molecular pump 55 as in the source chamber 30.

The scanner 51 is able to scan ±10 kV toward X axis and Y axis, and therefore, a sample of 4×4 inch size can be processed according to the present embodiment.

Also, a permanent magnet 52 of about 4000 gauss is installed in the process chamber 50 to change movement path of the cluster according to an acceleration energy of the cluster, and thereby the light monomer ions are digressed among the cluster to obtain even operating gas cluster ion beam.

An ion dose of the cluster can be calculated by installing a Faraday device 53 in the process chamber 50 and measuring ion current density. In addition, the size of the cluster can be measured by installing a channeltron 54 in the process chamber 50. The ion dose measured as above can be used for controlling the irradiation amount of the operating gas cluster ion beam.

In the embodiment of the present invention, the surface processing of the ITO thin film used for the transparent electrode such as the organic EL devices is described. However, the present invention can be applied for removing the hillock on the surface of ceramic or metal, and can be applied to surface cleaning (washing) by generalizing a plasma accelerator using electron drifting, increasing of surface adhesive force, plasma activation, vacuum deposition, fabrication of thin film, and plasma and ion etching.

Meanwhile, a principle and experiment of the surface smoothing device using the gas cluster ion beam according to the embodiment of the present invention will be described as follows.

The principle of the gas cluster ion beam will be described as follows. In cleaning (washing) and functioning the surface of the sample, the cluster is an agglomerate (a great molecule) including hundreds or thousands of atoms, and the adhesive force is very weak due to van-der Waals bonding (coupling). Most of the monoatoms are located on surface so as to have very high reactivity, and the constructing atoms share energy in case that the atoms are ionized and acceleration energy is added, and thereby low energy ion beam can be formed.

The sputtering yield is high about 10˜100 due to the impact of the great molecule and multiple impacts, and therefore a high speed etching can be made. In addition, the surface having a surface roughness of less than nanometer scale(unit) can be processed by transmitting momentum and energy in parellel to the surface. Also, implanted (infiltration) depth is very shallow, and therefore, it is useful for shallow junction formation (in case that the junction depth is) less than 100 nm for ULSI.

Meanwhile, the gas cluster ion is ion beam source having various characteristics, that is, if 100 kV acceleration energy is added to the ion, surfaces of materials having ultra hardness such as diamond, and quartz can be micro processed by using a surface erosion phenomenon.

Laval nozzle is fabricated and used for using the gas cluster ion, and a differential pumping system is fabricated so as to form the cluster by the adiabatic expansion. The generated cluster is ionized and accelerated to remove the hillock formed on the surface of the thin film and flattens the surface.

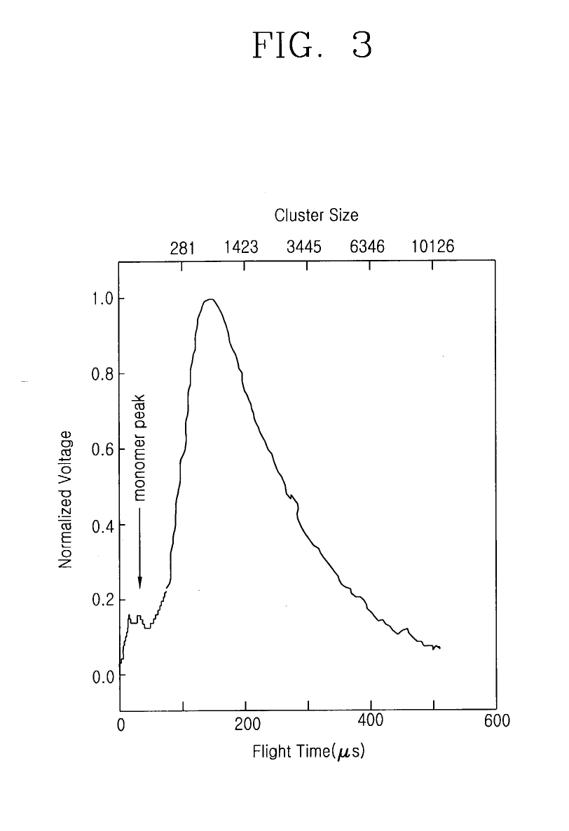

FIG. 3 is a graph showing CO₂ cluster measured using time-of-flight measurement method, when the cluster is passed through the convergent and divergent nozzle according to the present invention.

Herein, the pressure in the operating gas supplying device is 5 atm, and distribution of the gas cluster is measured using time-of-flight (the flight time) measurement method. At that time, 200 V pulse is applied to a first end of the einzel lens, the distribution of the cluster which passed for 10 μsec of shutter pulse time is measured using an oscilloscope from the channeltron 54 which is installed on a position 1.8 m from the einzel lens.

As shown in FIG. 3, a small peak shown at 50 μsec of flight time is flying distance of the CO₂ monomer ion, and the largest peak around 200 μs is the cluster including 750 CO₂ molecules. Therefore, an average size of the cluster is about 750 molecules.

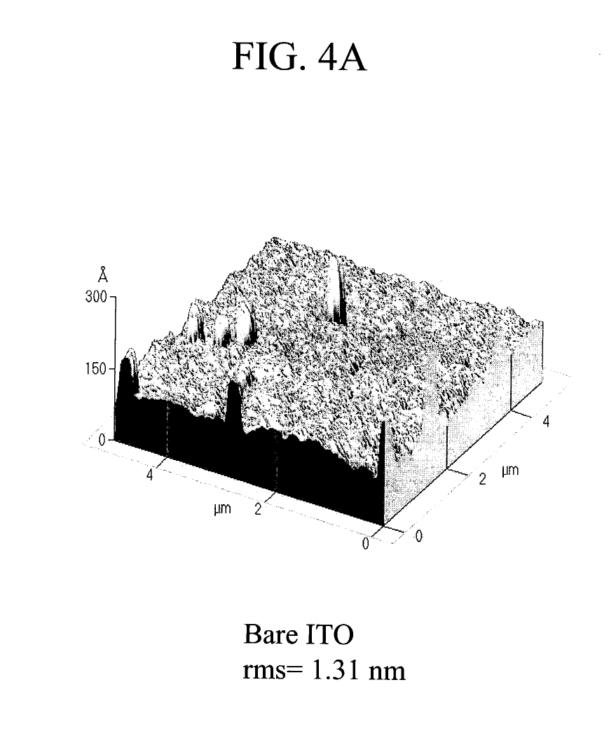

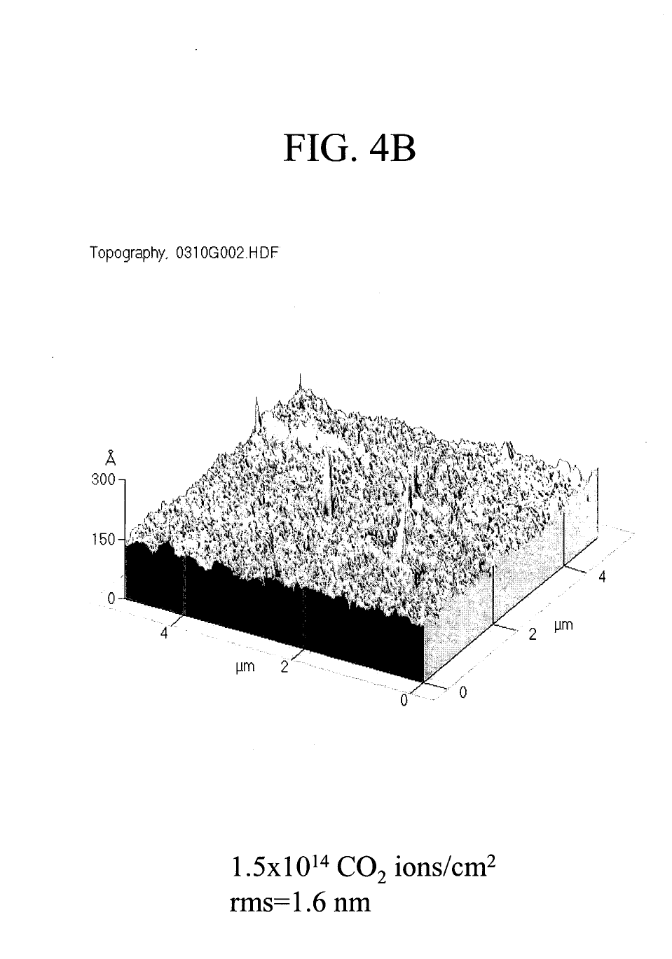

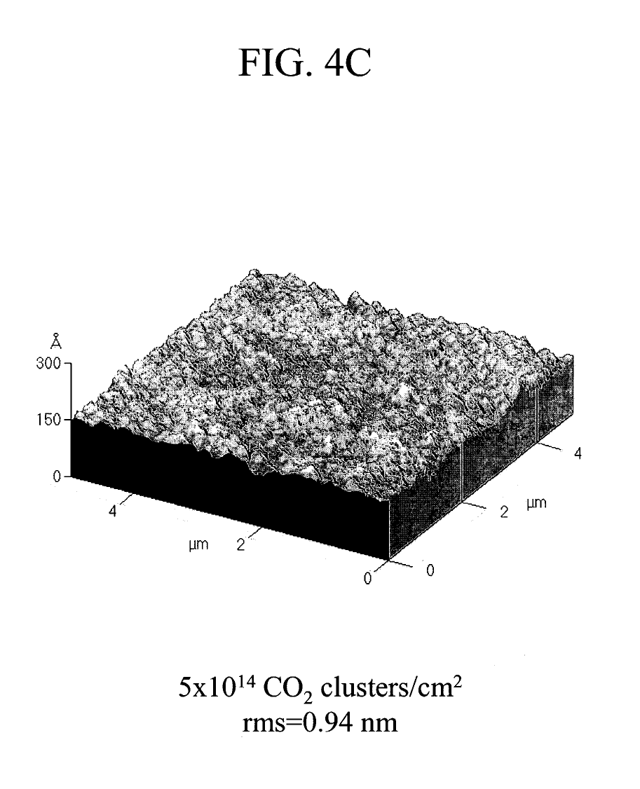

Meanwhile, FIGS. 4A, 4B, and 4C are respectively AFM images showing a surface of the ITO thin film, a surface processed using the CO₂ monomer ion beam, and a surface processed using the CO₂ cluster according to the present invention.

As shown in FIG. 4A, on the surface of the ITO thin film deposited on a glass before surface processing, a plurality of hillocks of 150˜100 Å are distributed. Even though there are many hillocks, the roughness of the surface is very flat about 1.31 nm (13.1 Å) when the surface is scanned using the AFM within 25 μm².

As shown in FIG. 4B, in case that 20 kV CO₂ monomer ion beam is irradiated of 1.5×10¹⁴ ions/cm² ion beam amount, the hillocks are very sharpened. And the surface roughness is 1.6 nm, and is not greatly improved.

On the contrary, as shown in FIG. 4C, in case that the surface of the ITO thin film is processed using the CO₂ cluster ion beam of 25 kV acceleration energy and of 5×10¹⁴ ions/cm² ion beam amount, the hillocks are all removed and the surface roughness becomes 0.94 nm. That is, when the clusters are irradiated on the surface, the momentum of the clusters are transferred by diffusion on the surface due to the size of the molecules, and therefore, the hillocks are removed by the moving in horizontal direction of the surface.

According to the surface smoothing device using the gas cluster ion beam of the present invention, cheap gases such as Ar, Ne, nitrogen, and oxygen can be used after increasing the ionizing efficiency by installing a simple cooling device, instead of expensive gases such as Xe and Kr conventionally used for the plasma accelerator using electron drifting.

Also, according to the surface smoothing device using the gas cluster ion beam of the present invention, damages on the surface is minimized and the hillock on the surface can be removed by rapid etching rate. And the surface roughness can be reduced less than nm (unit).

Also, according to the surface smoothing device using the gas cluster ion beam of the present invention, the hillocks which are on the surface of the material are removed, and thereby, even colors can be made and the life span can be increased by removing strong electric field effect which is concentrated on the hillock when it is used for the transparent electrode of the organic EL.

As the present invention may be embodied in several forms without departing from the spirit or essential characteristics thereof, it should also be understood that the above-described embodiments are not limited by any of the details of the foregoing description, unless otherwise specified, but rather should be construed broadly within its spirit and scope as defined in the appended claims, and therefore all changes and modifications that fall within the metes and bounds of the claims, or equivalence of such metes and bounds are therefore intended to be embraced by the appended claims.

What is claimed is:

1. A surface smoothing device comprising:
an operating gas supplying device for supplying operating gas;
a diffusion chamber connected to a convergent and divergent nozzle which changes the operating gas supplied from the operating gas supplying device into cluster state;
a source chamber including a skimmer connected to the diffusion chamber for extracting a part of the operating gas in cluster state, and an ionizing device for ionizing the operating gas of cluster state selected by the skimmer;
an acceleration chamber including a lens for increasing a cluster ion beam current, and an accelerating device for accelerating the cluster ion; and
a process chamber in which the accelerated cluster ion is irradiated on a sample to flatten a surface of the sample.

2. The device of claim 1, further comprising a scanner installed between the acceleration chamber and the process chamber for controlling a position of irradiating the operating gas in cluster state which is accelerated.

3. The device of claim 1, wherein the process chamber further comprises a Faraday for measuring electric current density of the irradiated operating gas.

4. The device of claim 3, wherein monomer ions in the accelerated operating gas in cluster state is removed by installing a permanent magnet in the process chamber.

5. The device of claim 4, the process chamber further comprises a channeltron which measures a size of the cluster of the operating gas which is irradiated.

6. The device of claim 3, the process chamber further comprises a channeltron which measures a size of the cluster of the operating gas which is irradiated.

7. The device of claim 1, wherein the operating gas is selected from the group of CO₂, SF₂, Ar, O₂, and N₂O.

8. The device of claim 1, wherein pressure in the operating gas supplying device is maintained to be larger than pressure of cluster generation for the operating gas.

9. The device of claim 1, wherein the lens is an einzel lens.

10. The device of claim 1, wherein the sample is an ITO thin film.

11. A surface smoothing method comprising:
forming cluster by passing operating gas through a convergent and divergent nozzle and adiabatically expanding the operating gas into a diffusion chamber;
extracting the generated cluster of the operating gas;
ionizing the extracted cluster;
accelerating the ionized cluster; and
flattening the surface by irradiating the accelerated cluster on a surface of a sample.

12. The method of claim 11, further comprising controlling a position of cluster irradiation after the accelerating step is completed.

13. The method of claim 12, further comprising a step of uniformizing the irradiated cluster by removing monomer ions using the permanent magnet before the flattening step.

14. The method of claim 11, further comprising a step of uniformizing the irradiated cluster by removing light monomer ions using the permanent magnet before the flattening step.

15. The method of claim 11, further comprising a step of focusing the ionized cluster after the ionizing step is completed.

16. The method of claim 15, wherein the ionized cluster is focused using an einzel lens.

17. The method of claim 11, wherein electric charge density of the cluster is controlled by measuring electric charge density of the irradiated cluster.

18. The method of claim 11, wherein a size of the cluster being irradiated is controlled by measuring size of the irradiated cluster.

19. The method of claim 11, wherein the operating gas is selected from the group of CO₂, SF₂, Ar, O₂, and N₂O.

20. The method of claim 11, wherein pressure in the operating gas supplying device is maintained to be larger than pressure of cluster generation of the operating gas.
